(19) United States
(12) Patent Application Publication
(10) Pub. No.: US 2025/0253882 A1
(43) Pub. Date: Aug. 7, 2025

(54) TRANSCEIVER CIRCUIT OPERABLE IN A DYNAMIC POWER RANGE

(71) Applicant: Qorvo US, Inc., Greensboro, NC (US)

(72) Inventors: Nadim Khlat, Cugnaux (FR); Ahmad Chaudhry, Oak Ridge, NC (US)

(21) Appl. No.: 18/855,225

(22) PCT Filed: Apr. 20, 2023
(86) PCT No.: PCT/US2023/019267

§ 371 Date: Oct. 8, 2024

Related U.S. Application Data
(60) Provisional application No. 63/348,502, filed on Jun. 3, 2022.
(60) Provisional application No. 63/408,159, filed on Sep. 20, 2022.

(51) Int. Cl. H04B 1/40; H03F 1/02; H03F 3/195; H03F 3/24

(52) U.S. Cl. CPC H04B 1/40; H03F 1/0222; H03F 3/195; H03F 3/245; H03F 2200/102; H03F 2200/105; H03F 2200/451

(57) ABSTRACT

A transceiver circuit operable in a dynamic power range is provided. In embodiments disclosed herein, the transceiver circuit is configured to generate a radio frequency (RF) signal and a target voltage that is adapted according to a power range of the RF signal. More specifically, the transceiver circuit is configured to generate the target voltage differently when the power range of the RF signal is higher (e.g., ≥18 dBm) or lower (e.g., <18 dBm). By adapting the target voltage based on the power range of the RF signal, it is possible to suppress a potential voltage ripple in a modulated voltage generated according to the target voltage to thereby achieve a desired adjacent channel leakage ratio (ACLR) when the RF signal is amplified at a power amplifier circuit based on the modulated voltage.

### RELATED APPLICATIONS

This application claims the benefit of U.S. provisional patent application Ser. No. 63/348,502, filed on Jun. 3, 2022, and U.S. provisional patent application Ser. No. 63/408,159, filed on Sep. 20, 2022, the disclosures of which are hereby incorporated herein by reference in their entireties.

### FIELD OF THE DISCLOSURE

The technology of the disclosure relates generally to a transceiver circuit capable of operating in a dynamic power range.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

A fifth-generation new radio (5G-NR) wireless communication system is widely regarded as a technological advancement that can achieve significantly higher data throughput, improved coverage range, enhanced signaling efficiency, and reduced latency compared to the existing third-generation (3G) and fourth-generation (4G) communication systems. A 5G-NR mobile communication device usually transmits and receives a radio frequency (RF) signal(s) in a millimeter wave (mmWave) RF spectrum that is typically above 6 GHz. Notably, the RF signal(s) transmitted in the mmWave RF spectrum may be more susceptible to propagation attenuation and interference that can result in a substantial reduction in data throughput. To help mitigate propagation attenuation and maintain desirable data throughput, the 5G-NR mobile communication device employs a power amplifier(s) to amplify the RF signal(s) before transmitting in the mmWave RF spectrum.

Envelope tracking (ET) and average power tracking (APT) are power management techniques designed to improve operating efficiency of the power amplifier(s). Specifically, the power amplifier(s) is configured to amplify the RF signal(s) from a time-variant input power to a time-variant output power based on a modulated voltage. The modulated voltage is typically generated based on a target voltage that keeps track of the time-variant input power of the RF signal(s). Understandably, the better the target voltage tracks the time-variant input power of the RF signal, the better the modulated voltage will be aligned with the time-variant input power. As a result, the time-variant output power can be more linearly related to the time-variant input power.

### SUMMARY

Embodiments of the disclosure relate to a transceiver circuit operable in a dynamic power range. In embodiments disclosed herein, the transceiver circuit is configured to generate a radio frequency (RF) signal and a target voltage that is adapted according to a power range of the RF signal. More specifically, the transceiver circuit is configured to generate the target voltage differently when the power range of the RF signal is higher (e.g., >18 dBm) or lower (e.g., <18 dBm). By adapting the target voltage based on the power range of the RF signal, it is possible to suppress a potential voltage ripple in a modulated voltage generated according to the target voltage to thereby achieve a desired adjacent channel leakage ratio (ACLR) when the RF signal is amplified at a power amplifier circuit based on the modulated voltage.

In one aspect, a transceiver circuit is provided. The transceiver circuit includes a signal processing circuit. The signal processing circuit is configured to generate an RF signal having a time-variant input power. The transceiver circuit also includes a target voltage circuit. The target voltage circuit is configured to determine a power range of the RF signal based on the time-variant input power. The target voltage circuit is also configured to generate a target voltage having a time-variant change across the determined power range.

In another aspect, a power management circuit is provided. The power management circuit includes a power amplifier circuit. The power amplifier circuit is configured to amplify an RF signal from a time-variant input power to a time-variant output power based on a modulated voltage. The power management circuit also includes a power management integrated circuit (PMIC). The PMIC is configured to generate the modulated voltage based on a target voltage. The power management circuit also includes a transceiver circuit. The transceiver circuit includes a signal processing circuit. The signal processing circuit is configured to generate the RF signal having the time-variant input power. The transceiver circuit also includes a target voltage circuit. The target voltage circuit is configured to determine a power range of the RF signal based on the time-variant input power. The target voltage circuit is also configured to generate the target voltage having a time-variant change across the determined power range.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a schematic diagram of an exemplary existing power management circuit wherein a transceiver circuit is configured to generate a radio frequency (RF) signal and a target voltage V_{TGT} based on a single lookup table (LUT);

FIG. 1B is a graphic diagram providing an exemplary illustration of the LUT in FIG. 1A;

FIG. 2 is a schematic diagram of an exemplary power management circuit wherein a transceiver circuit is configured to adapt a target voltage to ensure that a ripple voltage is canceled across a dynamic power range of an RF signal;

FIG. 3 is a schematic diagram of the transceiver circuit in FIG. 2 configured according to an embodiment of the present disclosure;

FIG. 4 is a graphic diagram providing an exemplary illustration of a high power-range (HPR) LUT and a low power-range (LPR) LUT employed by the transceiver circuit of FIG. 2 to adapt the target voltage in accordance with the dynamic power range of the RF signal; and

FIG. 5 is a schematic diagram of an exemplary user element wherein the power management circuit of FIG. 2 can be provided.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to a transceiver circuit operable in a dynamic power range. In embodiments disclosed herein, the transceiver circuit is configured to generate a radio frequency (RF) signal and a target voltage that is adapted according to a power range of the RF signal. More specifically, the transceiver circuit is configured to generate the target voltage differently when the power range of the RF signal is higher (e.g., ≥18 dBm) or lower (e.g., <18 dBm). By adapting the target voltage based on the power range of the RF signal, it is possible to suppress a potential voltage ripple in a modulated voltage generated according to the target voltage to thereby achieve a desired adjacent channel leakage ratio (ACLR) when the RF signal is amplified at a power amplifier circuit based on the modulated voltage.

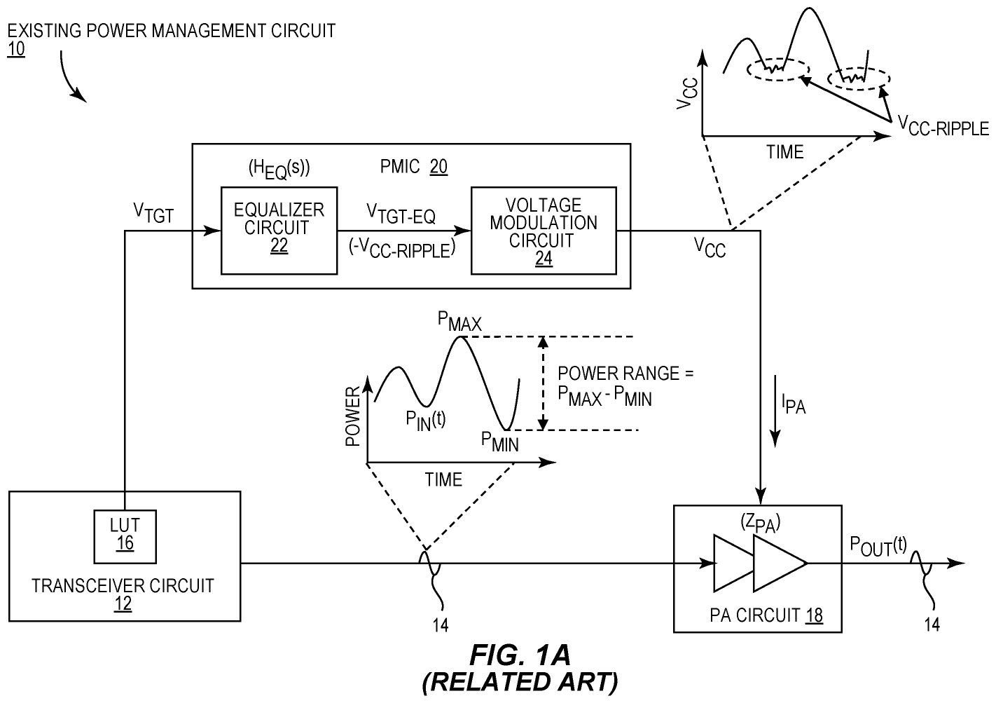

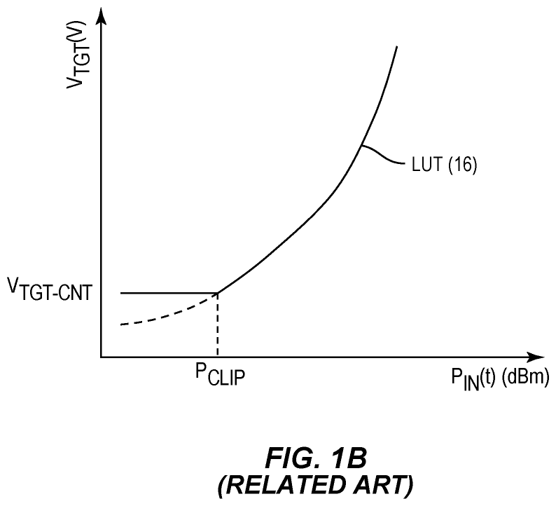

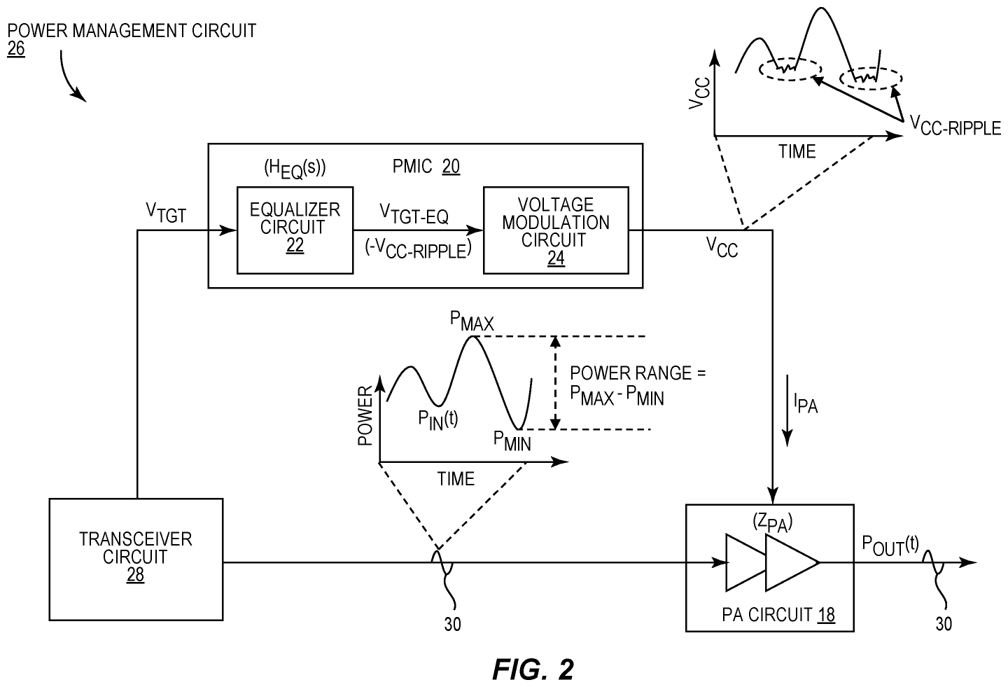

Before discussing the transceiver circuit of the present disclosure, starting at FIG. 2, an overview of an existing power management circuit that may suffer degraded ACLR as a result of a voltage ripple is first provided with reference to FIGS. 1A and 1B.

FIG. 1A is a schematic diagram of an exemplary existing power management circuit 10 wherein a transceiver circuit 12 is configured to generate an RF signal 14 and a target voltage V_{TGT} based on a single lookup table (LUT) 16. Herein, the transceiver circuit 12 is configured to generate the RF signal 14 with a time-variant input power P_{IN}(t) and the LUT 16 is configured to correlate the time-variant input power P_{IN}(t) with different levels of the target voltage V_{TGT}. Notably, the time-variant input power P_{IN}(t) can correspond to a power range that is defined by a maximum P_{MAX} and a minimum P_{MIN} of the time-variant input power P_{IN}(t).

FIG. 1B is a graphic diagram providing an exemplary illustration of the LUT 16. As shown in FIG. 1B, the target voltage V_{TGT} increases proportionally according to the time-variant input power P_{IN}(t) when the time-variant input power P_{IN}(t) is higher than a defined clipping threshold P_{CLIP} in the power range but is bottom clipped when the time-variant input power P_{IN}(t) is lower than or equal to the defined clipping threshold P_{CLIP}. In this regard, the LUT 16 will instead correlate the time-variant input power P_{IN}(t) with a constant target voltage V_{TGT-CNT} when the time-variant input power P_{IN}(t) is lower than or equal to the defined clipping threshold P_{CLIP}. Having the constant target voltage V_{TGT-CNT} when the time-variant input power P_{IN}(t) is lower than or equal to the defined clipping threshold P_{CLIP} can help establish a bottom of the target voltage V_{TGT}.

With reference back to FIG. 1A, the existing power management circuit 10 also includes a power amplifier circuit 18 and a power management integrated circuit (PMIC) 20. The power amplifier circuit 18 is configured to amplify the RF signal 14 from the time-variant input power P_{IN}(t) to a time-variant output power P_{OUT}(t) based on a modulated voltage V_{CC}. Understandably, when the power amplifier circuit 18 is operating with a linear gain, the time-variant output power P_{OUT}(t) will be linearly related to the time-variant input power P_{IN}(t) by the linear gain.

The PMIC 20 is configured to generate the modulated voltage V_{CC} based on the target voltage V_{TGT} and provide the modulated voltage V_{CC} to the power amplifier circuit 18. Notably, the power amplifier circuit 18 has an inherent impedance Z_{PA} that can cause a modulated current IPA in the power amplifier circuit 18 in response to receiving the modulated voltage V_{CC}. Given that the inherent impedance Z_{PA} can vary in accordance with, for example, the time-variant input power P_{IN}(t) and/or a modulated frequency of the RF signal 14, the modulated current IPA can interact with the modulated voltage V_{CC} to create a ripple voltage V_{CC-RIPPLE} in the modulated voltage V_{CC}. Understandably, since the modulated current IPA is associated with the time-variant input power P_{IN}(t), the ripple voltage V_{CC-RIPPLE} will exist across the entire power range of the RF signal 14.

The ripple voltage V_{CC-RIPPLE} may lead to a degraded linearity at the power amplifier circuit 18 and, as a result, cause a nonlinear relationship between the time-variant output power P_{OUT}(t) and the time-variant input power P_{IN}(t). Consequently, the RF signal 14 can potentially suffer a worsened ACLR.

To help suppress the ripple voltage V_{CC-RIPPLE}, the PMIC 20 can be configured to include an equalizer circuit 22 and a voltage modulation circuit 24. The equalizer circuit 22 is configured to apply an equalization filter H_{EQ}(s) to the target voltage to thereby create an equalized target voltage V_{TGT-EQ}. The voltage modulation circuit 24 is configured to generate the modulated voltage V_{CC} based on the equalized target voltage V_{TGT-EQ}.

More specifically, the equalizer circuit 22 is configured to add an opposite ripple voltage −V_{CC-RIPPLE} in the equalized target voltage V_{TGT-EQ} to cancel the ripple voltage V_{CC-RIPPLE}. As a result, the voltage modulation circuit 24 can generate the modulated voltage V_{CC} without the ripple voltage V_{CC-RIPPLE}.

In a non-limiting example, the equalization filter H_{EQ}(s) is a transfer function that is driven by a change dV_{TGT}/dt in the target voltage V_{TGT}. In this regard, when the transceiver circuit 12 generates the constant target voltage V_{TGT-CNT} in response to the time-variant input power P_{IN}(t) being lower than or equal to the defined clipping threshold P_{CLIP}, the equalizer circuit 22 will not be operational to apply the equalization filter H_{EQ}(S) to the target voltage V_{TGT}. As a result, the equalized target voltage V_{TGT-EQ} will not include the opposite ripple voltage −V_{CC-RIPPLE} to cancel the ripple voltage V_{CC-RIPPLE} across the entire power range of the RF signal 14. Consequently, the RF signal 14 can suffer a degraded ACLR.

Studies have shown that the ripple voltage V_{CC-RIPPLE} may be less problematic when the time-variant input power P_{IN}(t) is in a higher power range (e.g., 23 dBm), but can create a greater problem when the time-variant input power P_{IN}(t) is in a lower power range (e.g., 18 dBm). As such, the technical problem to be solved is to ensure that the equalizer circuit 22 is operational to add the opposite ripple voltage −V_{CC-RIPPLE} to cancel the ripple voltage V_{CC-RIPPLE} across a dynamic power range of the RF signal 14.

In this regard, FIG. 2 is a schematic diagram of an exemplary power management circuit 26 wherein a transceiver circuit 28 is configured to adapt a target voltage V_{TGT} to ensure that a ripple voltage V_{CC-RIPPLE} can be canceled across a dynamic power range of an RF signal 30. According to an embodiment of the present disclosure, the transceiver circuit 28 can be dropped into the existing power management circuit 10 to replace the transceiver circuit 12, without replacing the PMIC 20 and the power amplifier circuit 18. As such, it is possible to reuse the PMIC 20 and the power amplifier circuit 18 in the power management circuit 26 to help reduce cost and complexity associated with the upgrade. Accordingly, common elements between FIGS. 1 and 2 can be shown therein with common element numbers and will not be re-described herein.

Like the transceiver circuit 12 in the existing power management circuit 10, the transceiver circuit 28 is configured to generate the RF signal 30 with a time-variant input power P_{IN}(t). As described above in FIG. 1A, the RF signal 30 also has a power range that is defined by a maximum P_{MAX} and a minimum P_{MIN} of the time-variant input power P_{IN}(t). Accordingly, a dynamic power range of the RF signal 30 refers to a ratio between the maximum P_{MAX} and the minimum P_{MIN} of the time-variant input power P_{IN}(t).

Herein, the RF signal 30 is said to be in a high power-range (HPR) when the power range of the RF signal 30 is greater than or equal to 18 dBm (e.g., 23 dBm) or in a low power-range (LPR) when the power range of the RF signal 30 is lower than 18 dBm. Notably in the power management circuit 26, the power amplifier circuit 18 and the PMIC 20 will each operate in a same fashion as described in FIG. 1A.

As described in detail below, the transceiver circuit 28 is configured to ensure that a time-variant change dV_{TGT}/dt in the target voltage V_{TGT} will always occur when the RF signal 30 is in the LPR such that the equalizer circuit 22 can always generate the equalized target voltage V_{TGT-EQ} with the opposite ripple voltage −V_{CC-RIPPLE}. In contrast, when the RF signal 30 is in the HPR, the equalizer circuit 22 will operate in the same fashion as in the existing power management circuit 10. As such, the power management circuit 26 can achieve an improvement in ACLR over the existing power management circuit 10, especially when the RF signal 30 is in the LPR. In this regard, the power management circuit 26 provides a solution to the technical problem described above.

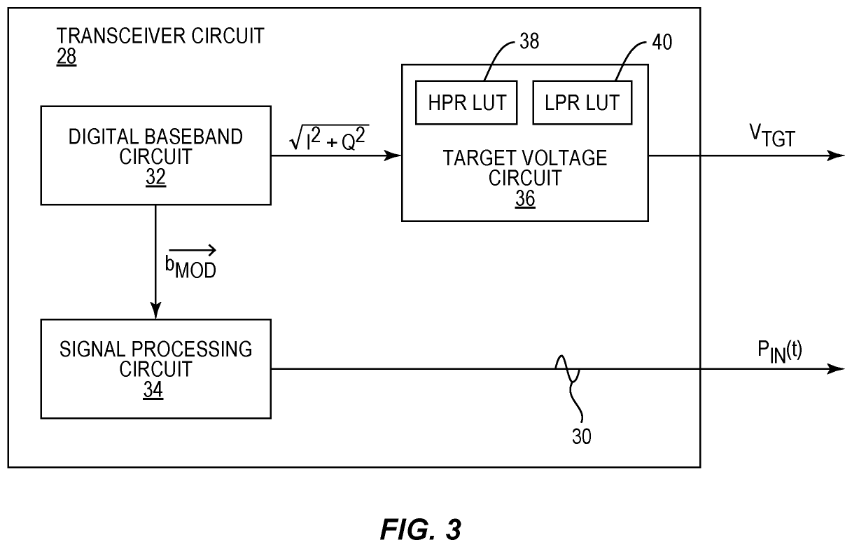

FIG. 3 is a schematic diagram of the transceiver circuit 28 in FIG. 2 configured according to an embodiment of the present disclosure. Common elements between FIGS. 2 and 3 are shown therein with common element numbers and will not be re-described herein.

Herein, the transceiver circuit 28 includes a digital baseband circuit 32, a signal processing circuit 34, and a target voltage circuit 36. The digital baseband circuit 32 is configured to generate an input vector \vec{b_{MOD}}. In a non-limiting example, the input vector \vec{b_{MOD}} is so generated to include an in-phase component (I) and a quadrature component (0). In this regard, the input vector \vec{b_{MOD}} will be associated with a time-variant amplitude \sqrt{I¹+Q²} that ultimately defines the time-variant input power P_{IN}(t).

The signal processing circuit 34, which may include a digital-to-analog converter (DAC) and/or a frequency converter (not shown), is configured to generate the RF signal 30 from the input vector \vec{b_{MOD}} and provide the RF signal 30 to the power amplifier circuit 18 in FIG. 2. Understandably, since the RF signal 30 is generated from the input vector \vec{b_{MOD}}, the RF signal 30 will be associated with the time-variant input power P_{IN}(t) that tracks (increases or decreases) the time-variant amplitude \sqrt{I¹+Q²}. In other words, it is possible to determine the power range (e.g., LPR or HPR) of the RF signal 30 based on the time-variant amplitude \sqrt{I²+Q²}.

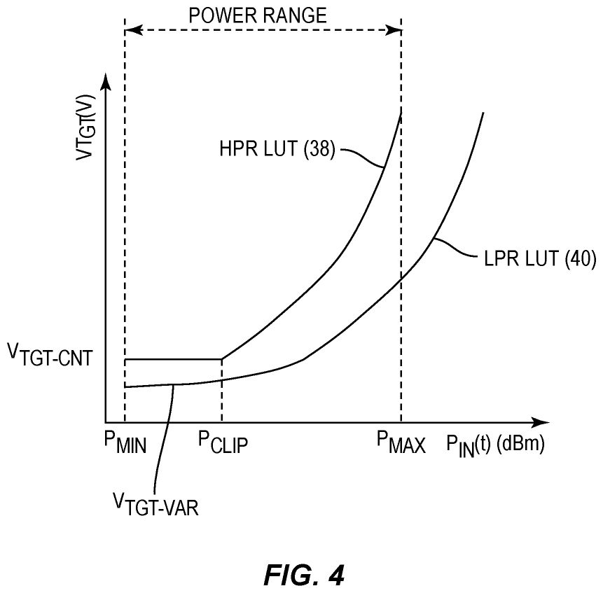

In an embodiment, the target voltage circuit 36 can include a HPR LUT 38 and a LPR LUT 40. FIG. 4 is a graphic diagram providing an exemplary illustration of the HPR LUT 38 and the LPR LUT 40 in FIG. 3. Common elements between FIGS. 3 and 4 are shown therein with common element numbers and will not be re-described herein.

Herein, the HPR LUT 38 is identical to the LUT 16, as illustrated in FIG. 1B. In this regard, the target voltage V_{TGT} increases proportionally according to the time-variant input power P_{IN}(t) when the time-variant input power P_{IN}(t) is higher than the defined clipping threshold P_{CLIP} but is bottom clipped when the time-variant input power P_{IN}(t) is lower than or equal to the defined clipping threshold P_{CLIP}. Like the LUT 16, the HPR LUT 38 will instead correlate the time-variant input power P_{IN}(t) with the constant target voltage V_{TGT-CNT} when the time-variant input power P_{IN}(t) is lower than or equal to the defined clipping threshold P_{CLIP}.

In contrast, the LPR LUT 40 is configured to correlate the time-variant input power P_{IN}(t) with a non-constant target voltage V_{TGT-VAR} when the power range of the input vector is lower than or equal to the defined clipping threshold P_{CLIP}. In a non-limiting example, the LPR LUT 40 can correspond to a small slope to cause a small time-variant change dV_{TGT}/dt (e.g., up to 200 mV) in the target voltage V_{TGT}. The small time-variant change dV_{TGT}/dt, although small, is sufficient to trigger the equalizer circuit 22 to generate the equalized target voltage V_{TGT-EQ} with the opposite ripple voltage −V_{CC-RIPPLE} to thereby cancel the ripple voltage V_{CC-RIPPLE} in the modulated voltage V_{CC}.

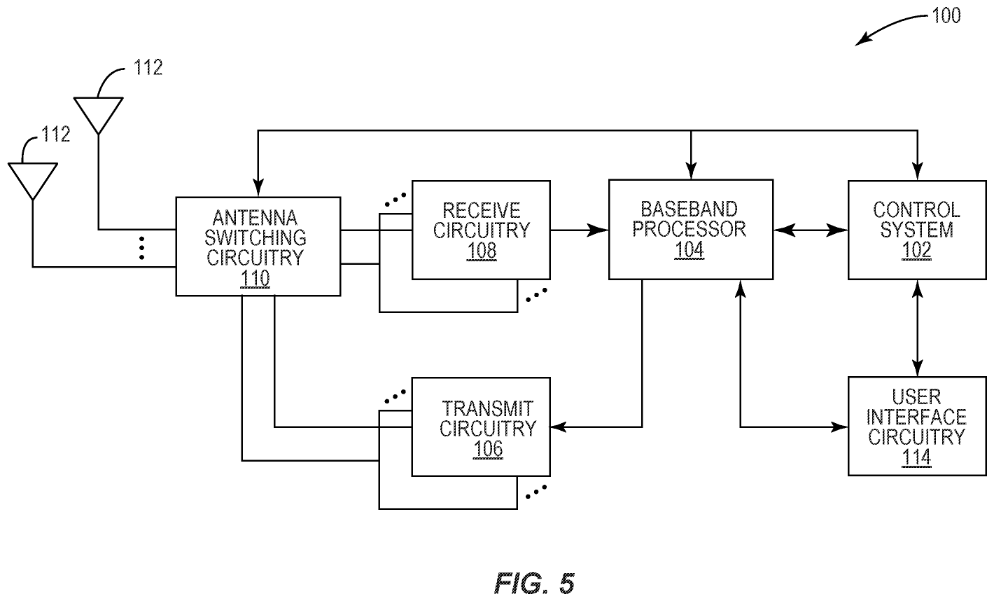

The power management circuit 26 of FIG. 2 can be provided in a user element to enable bandwidth adaptation according to embodiments described above. In this regard, FIG. 5 is a schematic diagram of an exemplary user element 100 wherein the power management circuit 26 of FIG. 2 can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

Those skilled in the art will recognize improvements and modifications to the preferred embodiments of the present disclosure. All such improvements and modifications are considered within the scope of the concepts disclosed herein and the claims that follow.

1. A transceiver circuit comprising:
a signal processing circuit configured to generate a radio frequency (RF) signal having a time-variant input power; and
a target voltage circuit configured to:
determine a power range of the RF signal based on the time-variant input power; and
generate a target voltage having a time-variant change across the determined power range.

2. The transceiver circuit of claim 1, further comprising a digital baseband circuit configured to generate an input vector having a time-variant amplitude, wherein the signal processing circuit is further configured to convert the input vector into the RF signal having the time-variant input power tracking the time-variant amplitude of the input vector.

3. The transceiver circuit of claim 1, wherein the target voltage circuit comprises:
a high power-range (HPR) lookup table (LUT) configured to correlate the time-variant input power with the time-variant change in the target voltage when the determined power range is higher than a defined clipping threshold; and
a low power-range (LPR) LUT configured to correlate the time-variant input power with the time-variant change in the target voltage when the determined power range is lower than or equal to the defined clipping threshold.

4. The transceiver circuit of claim 3, wherein:
the HPR LUT is further configured to correlate the time-variant input power with a constant target voltage when the time-variant input power is lower than or equal to the defined clipping threshold; and
the LPR LUT is further configured to correlate the time-variant input power with a non-constant target voltage when the time-variant input power is lower than or equal to the defined clipping threshold.

5. The transceiver circuit of claim 3, wherein the target voltage circuit is further configured to:
generate the target voltage based on the HPR LUT when the determined power range is higher than the defined clipping threshold; and
generate the target voltage based on the LPR LUT when the determined power range is lower than or equal to the defined clipping threshold.

6. A power management circuit comprising:
a power amplifier circuit configured to amplify a radio frequency (RF) signal from a time-variant input power to a time-variant output power based on a modulated voltage;
a power management integrated circuit (PMIC) configured to generate the modulated voltage based on a target voltage; and
a transceiver circuit comprising:
a signal processing circuit configured to generate the RF signal having the time-variant input power; and
a target voltage circuit configured to:
determine a power range of the RF signal based on the time-variant input power; and
generate the target voltage having a time-variant change across the determined power range.

7. The power management circuit of claim 6, wherein:
the power amplifier circuit causes a modulated current that interacts with the modulated voltage to create a ripple voltage in the modulated voltage across the power range of the RF signal; and
the target voltage circuit is further configured to generate the target voltage to thereby cause the ripple voltage to be cancelled across the power range of the RF signal.

8. The power management circuit of claim 7, wherein the PMIC comprises:
an equalizer circuit configured to apply an equalization filter to the target voltage to thereby create an equalized target voltage; and
a voltage modulation circuit configured to generate the modulated voltage based on the equalized target voltage.

9. The power management circuit of claim 8, wherein:
the equalizer circuit is further configured to apply the equalization filter to the target voltage to thereby add an opposite ripple voltage in the equalized target voltage; and
the voltage modulation circuit is configured to generate the modulated voltage comprising the opposite ripple voltage to thereby cancel the ripple voltage in the modulated voltage.

10. The power management circuit of claim 9, wherein:
the equalization filter is configured to add the opposite ripple voltage in the equalized target voltage in response to the time-variant change of the target voltage; and
the target voltage circuit is further configured to generate the target voltage having the time-variant change across the power range of the RF signal.

11. The power management circuit of claim 6, further comprising a digital baseband circuit configured to generate an input vector having a time-variant amplitude, wherein the signal processing circuit is further configured to convert the input vector into the RF signal having the time-variant input power tracking the time-variant amplitude of the input vector.

12. The power management circuit of claim 6, wherein the target voltage circuit comprises:
a high power-range (HPR) lookup table (LUT) configured to correlate the time-variant input power with the time-variant change in the target voltage when the determined power range is higher than a defined clipping threshold; and
a low power-range (LPR) LUT configured to correlate the time-variant input power with the time-variant change in the target voltage when the determined power range is lower than or equal to the defined clipping threshold.

13. The power management circuit of claim 12, wherein the time-variant change in the target voltage is less than two-hundred millivolts when the determined power range is lower than or equal to the defined clipping threshold.

14. The power management circuit of claim 12, wherein:
the HPR LUT is further configured to correlate the time-variant input power with a constant target voltage when the time-variant input power is lower than or equal to the defined clipping threshold; and
the LPR LUT is further configured to correlate the time-variant input power with a non-constant target voltage when the time-variant input power is lower than or equal to the defined clipping threshold.

15. The power management circuit of claim 14, wherein the target voltage circuit is further configured to:
generate the target voltage based on the HPR LUT when the determined power range is higher than the defined clipping threshold; and
generate the target voltage based on the LPR LUT when the determined power range is lower than or equal to the defined clipping threshold.
